(19) United States
(12) Patent Application Publication
(10) Pub. No.: US 2014/0196943 A1
(43) Pub. Date: Jul. 17, 2014

(54) Resilient Adherent EMI Shielding Member

(71) Applicant: Molex Incorporated, Lisle, IL (US)

(72) Inventor: Christopher D. HIRSCHY, Conway, AR (US)

(73) Assignee: MOLEX INCORPORATED, Lisle, IL (US)

(21) Appl. No.: 13/739,661

(22) Filed: Jan. 11, 2013

(51) Int. Cl. H05K 9/00

(52) U.S. Cl. CPC H05K 9/0052
USPC 174/382

(57) ABSTRACT

In order to prevent EMI leakage from various openings formed in module-receiving receptacles, a flexible, conductive shield member is provided. The shield member may have multiple layers but includes at least a conductive layer and an adhesive layer. The adhesive layer permits the shield member to be applied to an exterior surface of the receptacle and the shield member is further configured and dimensioned such that it fits entirely over the opening with a sufficient marginal extent to remain in place on the receptacle and provide its EMI barrier function effectively. communicating with the interior portion, and the bottom is configured to be joined to a circuit board. An EMI shield member is provided along the bottom of the cage and extends completely around the bottom opening to be held between the cage and a circuit board. The EMI shield member forms a shielded interface completely around the perimeter of the bottom opening.

### BACKGROUND OF THE PRESENT DISCLOSURE

The Present Disclosure relates generally to structures associated with electronic modules for reducing electromagnetic interference (EMI) radiation therefrom, and more particularly to a cost-effective and easily applied shielding member for use with a shielding cage housing a connector on a printed circuit board and which receives an electronic module therein, that mates to the connector.

Electronic modules are used to connect various electronic devices together. Such modules are usually terminated to opposing ends of a cable to define a cable assembly that is used to interconnect a server to a router, for example. Such modules may incorporate fiber optic, electrical or combined transceivers formed in the shape of a plug and the plugs are received within receptacles that are disposed within electrical equipment. These receptacles can include metal or die cast guide frames or sheet metal or metalized cages to form a conductive receptacle. Such a receptacle commonly includes opposing top and bottom walls, opposing side walls joining the top and bottom walls together to define a four walled enclosure. A rear wall typically interconnects the side walls and top walls together with an opening formed in the bottom wall so that the receptacle can be mounted to a circuit board over a connector, which is also mounted to the circuit board.

These modules are often constructed in accordance with various standards that dictate the size and compatibility so that modules can be used interchangeably within a standard. These standards are now envisioning data transfer rates of 2.5 gigabytes per second (GBPS) and upwards of 10 GBPS or greater. At such high data transfer speeds, the modules generate electromagnetic energy. As the amount of such energy increases, this energy passes through gaps present in the receptacle/cage to an extent that it generates EMI that adversely affects the transmission of data signals through the module, and the adjacent modules of the associated electronic equipment to which it is connected. It is therefore desirable to shield data signals from EMI to the entire extent of the receptacle.

In most cage-style receptacles, conductive gaskets are utilized to provide EMI shielding. These gaskets may include pliable structures, such as that described in U.S. Pat. No. 6,752,663, the content of which is hereby incorporated herein by reference in its entirety, which describes a conductive foam gasket that extends along three sides of the receptacle bottom opening. Or, as also described in the '633 Patent, gaskets may be formed as a separate metal spring that is positioned along a fourth side of the receptacle/cage opening. Such metal springs are usually stamped and formed into gasket structures that have a plurality of thin metal spring fingers. These metal spring gaskets are applied to the receptacle/cages around openings where the are mounted to the circuit board or where an opening is present that defines an insertion passage for an electronic module.

Shielding cages are being provided with more openings formed in the receptacle/cage walls where the cage is stamped and formed to provide a module stop, a heat sink attachment clip, a module retainer, or lock and the like. Metal spring gaskets can cost more than a dollar to manufacture and apply and the use of them to contain EMI at these type of openings is difficult due to the locations of the openings, as well as difficulty in attaching them to the cage so they can cover the openings in an effective EMI shielding manner. Accordingly, a need exists for a cost-effective EMI shielding gasket that can be used in association with receptacle/cage openings and which can be applied thereto either manually or robotically at minimal cost.

### SUMMARY OF THE PRESENT DISCLOSURE

In accordance with an exemplary embodiment of the Present Disclosure, an improved EMI shielding gasket is provided for use in sealing off openings formed in receptacles and/or cages. Such receptacles usually take the form of a rectangular, hollow enclosure defined by a plurality of walls. Openings are formed in the receptacle walls to form various structural features, such as insertion stops for electronic modules, anchor slips for heat sinks, receptacle keys, receptacle latching members and the like. All of these openings have in common the fact that for the most part, they are defined by a minimum of three sides and most often four or more sides. Typically, the openings are stamped in a single plane of the receptacle or cage body such that part of the cage forms a boundary around the opening, or alternatively, they may extend within two, adjoining planes.

A shield member in the form of an adhesive-backed conductive label or pad is provided having a general overall diameter of the corresponding cage opening. The shield member may be formed of a first layer of a conductive, pliable material such as a foam or it may include a layer of a static-dissipative material to which an adhesive layer is attached. Importantly, the labels have at least an initial planar configuration that permits them to be applied to openings in one plane of the cage, but the planar configuration preferably has an extent that permits the label to be folded into contact with a second plane of the cage that is adjoining the cage one plane. Also, it is preferred that the label be substantially impervious, that is air-tight, so that the labels may be easily acquired by a vacuum pick up device and discharged by the same during application. The planar nature of the labels makes it easy for optical recognition technology to be used in their application to the cage openings. Preferably, the shield member has a thickness of at least about 0.008 to 0.015 inches and it may exceed those dimensions. It is stable enough that it can be moved by way of the vacuum pick-up manner described above without compromising the planar nature of the shield member, such as by wrinkling

### BRIEF DESCRIPTION OF THE FIGURES

The organization and manner of the structure and operation of the Present Disclosure, together with further objects and advantages thereof, may best be understood by reference to the following Detailed Description, taken in connection with the accompanying Figures, wherein like reference numerals identify like elements, and in which:

FIG. 1 is a perspective view of a module-receiving receptacle, or cage, with the cage body illustrated as having a plurality of openings disposed therein;

FIG. 2 is the same view as FIG. 1, but with a like plurality of pliable EMI shield members constructed in accordance with the principles of the Present Disclosure applied over the openings;

FIG. 3 is a partial detail view of the cage of FIG. 1, but with the shield members shown removed and spaced apart therefrom in order to show the relative dimensions of the cage openings and the pliable shield members;

FIG. 4 is a diagrammatic view of a configuration of a cage opening and of the configuration of an associated pliable shield member intended for covering the cage opening;

FIG. 5A is a sectional view of a shield member of the Present Disclosure having three layers;

FIG. 5B is a sectional view of another embodiment of a shield member of the Present Disclosure which has two layers; and

FIG. 6 is a perspective view of a shield member of the Present Disclosure intended for covering a cage opening that extends in two different planes.

### DESCRIPTION OF THE PREFERRED EMBODIMENTS

While the Present Disclosure may be susceptible to embodiment in different forms, there is shown in the Figures, and will be described herein in detail, specific embodiments, with the understanding that the Present Disclosure is to be considered an exemplification of the principles of the Present Disclosure, and is not intended to limit the Present Disclosure to that as illustrated.

As such, references to a feature or aspect are intended to describe a feature or aspect of an example of the Present Disclosure, not to imply that every embodiment thereof must have the described feature or aspect. Furthermore, it should be noted that the description illustrates a number of features. While certain features have been combined together to illustrate potential system designs, those features may also be used in other combinations not expressly disclosed. Thus, the depicted combinations are not intended to be limiting, unless otherwise noted.

In the embodiments illustrated in the Figures, representations of directions such as up, down, left, right, front and rear, used for explaining the structure and movement of the various elements of the Present Disclosure, are not absolute, but relative. These representations are appropriate when the elements are in the position shown in the Figures. If the description of the position of the elements changes, however, these representations are to be changed accordingly.

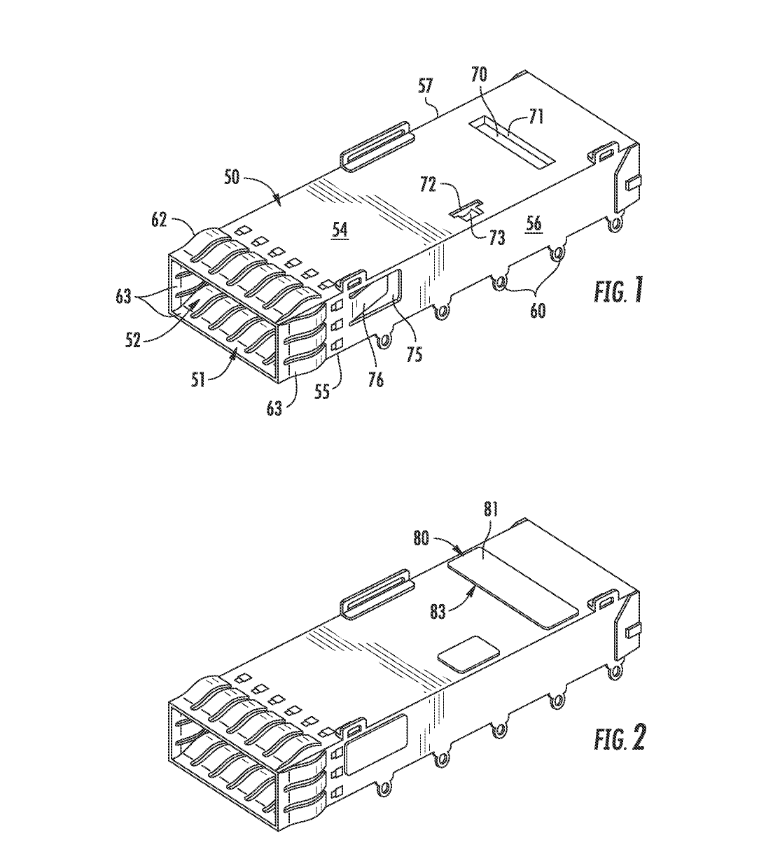

FIG. 1 illustrates a receptacle, or cage, 50 for use in electronic equipment and having a hollow interior 52 configured to receive a single electronic module, either copper of fiber optic (not shown) therein. As such, the receptacle 50 includes opposing top and bottom walls 54, 55 and side walls 56, 57 that are combined together by way of slots and tabs as is known in the art to form a generally rectangular receptacle that has an opening in its bottom wall 55 that permits the receptacle 50 to be applied to a circuit board over an internal connector that is mounted to the circuit board.

The receptacle 50 may be mounted to a circuit board and noted, and this mounting typically occurs by way of a plurality of mounting pins, illustrated as compliant pins 60 formed as part of the receptacle 50, either as part of the side walls 56, 57 or formed from the bottom wall 55. These compliant pins 60 are received within corresponding mounting holes, or vias formed in the circuit board. A compressible conductive gasket 62 in the form of either a collar member, or four separate gasket portions, 63 may be applied to the exterior of the receptacle 50 near the front end 51 thereof and positioned to make contact with the walls defining an opening in a bezel, or faceplate (not shown). This collar member 63 may have a plurality of elongated spring fingers 64, or other suitable spring members formed therewith configured to selectively engage a module inserted into the receptacle opening, as well as the exterior faceplate. The collar member 63 is formed from a conductive material so that the spring fingers 64 will create a plurality of electrical contact points between the conductive receptacle 50 and the surrounding faceplate to effectively prevent a measure of EMI from leaking out of the receptacle 50.

The receptacle 50 may have other openings disposed in its body along its walls 54, 56, 57, all of which may form portals for the emission of EMI. Such openings may include an internal module stop opening 70 that encloses a vertical stop 71 formed from the top wall 54 and bent downwardly into the receptacle interior 52 to provide a stop surface that abuts against an end of an inserted module, or they may include an internal key opening 72 that encloses includes a tang, or arm, 73 stamped from the receptacle top wall 54 and which projects inwardly of the receptacle 50 and which acts as a stop for improperly inserted modules as is known in the art. Yet other openings 75 may be formed in the sidewalls 56, 57 of the receptacle 50 which enclose cantilevered latch members 76 that extend inwardly and which engage a properly oriented and fully inserted module. All of these openings 70, 72, 75 define portals through which EMI may escape from the module and internal connector during high speed data transmission.

It has been found that an effective EMI shield can be obtained by utilizing shield member in the form of a layered material that has an adherent aspect to it that permits it to be applied to the exterior surfaces of the receptacle 50 in a manner to cover the entire openings. Such a layered shield member 80 is shown in section in FIG. 5a, and it may include a conductive layer 81 which may be a very thin metal sheet, conductive plastic or metal deposit and a substrate layer 82 such as a conductive foam, a flexible plastic, gel, elastomeric with conductive material contained therein and a pressure sensitive adhesive layer 83. In an alternate embodiment, the shield member 80 may include just the conductive layer 81 and an adhesive layer 83. The shield member 80 preferably is larger in size than its associated receptacle opening 70, 72, 75 and preferably the overall dimensions should be greater by a factor of about 25% or one-quarter of the least dimension of the opening.

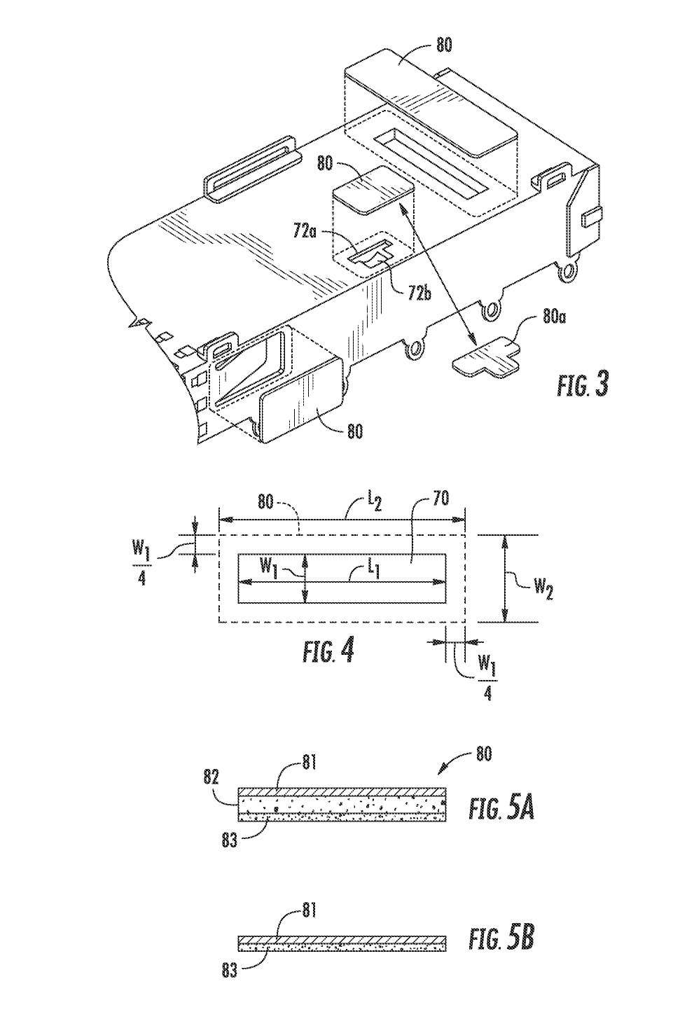

This is illustrated diagrammatically in FIG. 4 where an opening 70 is shown having dimensions L₁ and W₁ and the dimensions of the corresponding shield member 80 have dimensions L₂ and W₂. In order to provide for effective registration and placement of the shield member 80 over the openings, it is preferred that the marginal dimensions of the shield member be least 25% greater than the least dimension of the opening. Hence, the shield member 80 as outlined in dashed lines in FIG. 4 has a length L₂ equal to the length of the opening and two marginal lengths (with each marginal length being equal to about L₁/4), or L₂=L₁/4+L₁+L₁/4. Similarly, the preferred width of the shield member is W₂=W₁/4+W₁+W₁/4. In this manner, the shield members have a marginal extent that completely surrounds the opening and contacts the opposing wall of the receptacle to eliminate any gaps between the two through which EMI could emanate, thereby forming a reliable EMI barrier on the surface of the receptacle. As shown in FIG. 3, the shield member 80 associated with the T-shaped opening 72 may be rectangular or square, rather than T-shaped and if so, the one-quarter (25%) marginal extent will be realized along the top and bottom edges 72a, 72b of the T, rather than along the sides of the T-shaped opening 72.

The conductive layer 81 may also be formed from a static dissipative material, such as electrostatic discharge material or may include purely insulative materials such as polypropylene or other polymeric materials that are metallized and which include a conductive metal layer that is deposited, embedded or encapsulated within the insulative material. As such, these shield members produce an effective EMI shield and are cost-effective compared to a formed EMI spring gasket, which is stamped and formed and which needs to have a configuration that permits it to be attached to the receptacle at the opening. The shield members of the Present Disclosure are generally planar members and easily applied by automation or human labor. Suitable metals for forming the conductive layer include aluminum, copper, gold, silver, tin and alloys thereof

The shield member preferably has a thickness of at least between about 0.008-0.015 inches, and larger thicknesses are suitable. Preferably the thickness is such that the shield member 80 will retain its planar configuration so that it may be picked up off a supply feed by robotic means, such as a vacuum pick-up tube 88, without wrinkling or crumpling, which would possibly lead to imperfect adherence of the shield member around the perimeter of the opening. Such thickness would also prevent wrinkling if the shield member were manually removed form a supply feed and applied to the receptacle. These are merely examples of different application processes.

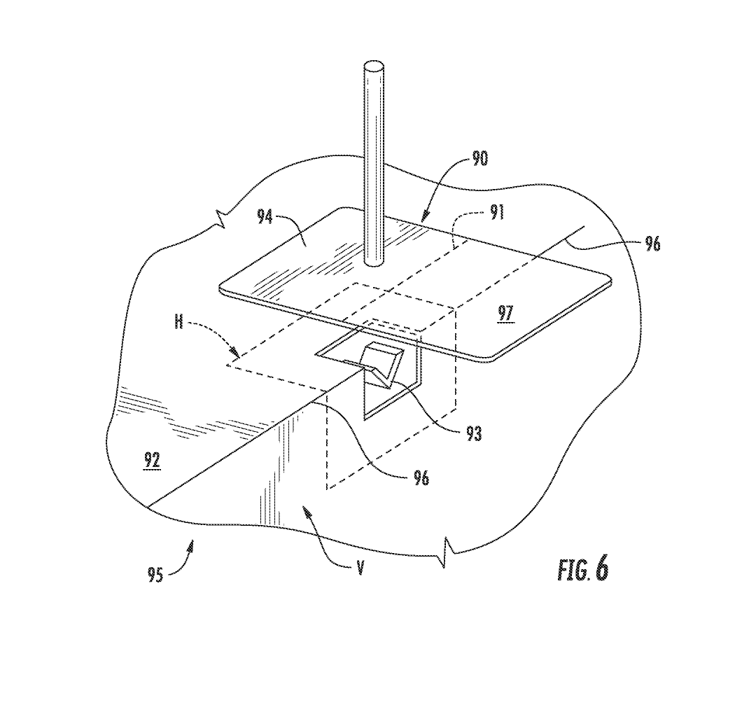

The shield members 80 may have configurations that match that of their corresponding openings, i.e., rectangular, square, circular, T-shaped, L-shaped or the like. In this manner, shield members that differ in configuration can be accurately applied to their proper opening by way of optical recognition and matching. Also, in this manner, and due to the flexible nature of the layers that make up each shield member, as shown in FIG. 6, the shield member 90 may have an alignment indicator on it, such as a line 91 that may be used to align the shield member 90 in place opposite the receptacle body 92 and associated opening 93 along an edge 96 of the receptacle 95, so that a first portion 94 of the shield member may first be applied in a first plane to the receptacle 95 (shown as a horizontal plane H) and a second portion 97 may be secondly applied in a second plane (shown as a vertical plane V) to the receptacle. This may be done either in an automated manner, such as by a robot or manually.

While a preferred embodiment of the Present Disclosure is shown and described, it is envisioned that those skilled in the art may devise various modifications without departing from the spirit and scope of the foregoing Description and the appended Claims.

What is claimed is:

1. A receptacle assembly, comprising:
a hollow conductive shielding cage having a front end with an opening communicating with a hollow interior portion thereof, the opening configured to receive a module therein, the shielding cage including a plurality of walls, the walls including at least two opposing sidewalls, and at least one top interconnecting the sidewalls together, the shielding cage configured to mount to a circuit board; and
the shielding cage including at least a first opening, disposed in one of the top and sidewalls, the first opening having a first configuration, and a flexible, conductive shield member having a second configuration, similar to the first configuration but slightly larger thereof so as to provide a marginal extent extending around a perimeter of the first opening, the shield member being adhered to the shielding cage around the perimeter of said first opening so as to provide a barrier to EMI leakage from the shielding cage.

2. The receptacle assembly of claim 1, wherein the shield member includes a conductive layer and a pressure-sensitive adhesive layer.

3. The receptacle assembly of claim 2, wherein the conductive layer is planar and the shield member has a thickness sufficient to resist wrinkling when contacted and applied by a vacuum pick-up tube.

4. The receptacle assembly of claim 1, where the shield member is a multilayered material including at least a substrate layer, a conductive layer disposed along one surface of the substrate layer and an adhesive layer disposed along another surface of the substrate layer.

5. The receptacle assembly of claim 4, wherein one of the layers includes an elastomeric with conductive particles disposed therein.

6. The receptacle assembly of claim 1, wherein the contact points include impressions formed in the shield member.

7. The receptacle assembly of claim 1, wherein the first opening extends in a first plane along one of the shielding cage walls.

8. The receptacle assembly of claim 1, wherein the first opening extends in two planes along two of the shielding cage walls.

9. The receptacle assembly of claim 1, wherein the shield member marginal extent is equal to about one-quarter of the least dimension of the first opening.

10. The receptacle assembly of claim 1, further including a second opening disposed in one of the top and sidewalls and a second flexible, conductive shield member, the second opening having a third configuration different than the first opening configuration, the second shield member having a fourth configuration, the third and fourth configuration being similar to each other but different from the first and second configurations.

11. The receptacle assembly of claim 1, wherein the shield member has a thickness of at least between about 0.008-0.015 inches.

12. A shield member for providing an EMI barrier to an opening disposed in a module receptacle, the opening having a first configuration and being disposed in at least one wall of the receptacle, the shield member comprising:
a flexible, layered shield label including a conductive layer and at least an adhesive layer, the shield label having a thickness sufficient to permit application to an exterior surface of the receptacle without wrinkling and via either a vacuum or manual pick-up and application process.

13. The shield member of claim 12, further including a substrate layer interposed between the conductive and adhesive layers.

14. The shield member of claim 12, wherein the adhesive layer includes a pressure-sensitive adhesive.

15. The shield member of claim 12, wherein the shield label has a second configuration similar to the opening first configuration.

16. The shield member of claim 12, wherein the shield label has a third configuration different than the opening first configuration.

17. The shield member of claim 12, wherein the shield label is larger in size than the receptacle first opening such that it has a marginal extent that extends completely around a perimeter of the first opening.

18. The shield member of claim 17, wherein the marginal extent is at least one-quarter of a least dimension of the first opening.
